(19) United States
(12) Patent Application Publication
(10) Pub. No.: US 2026/0205058 A1
(43) Pub. Date: Jul. 16, 2026

(54) POWER DISTRIBUTOR CIRCUITS FOR LOAD MODULATED AMPLIFIERS

(71) Applicant: Qorvo US, Inc., Greensboro, NC (US)

(72) Inventors: Alexander Titanov, Morrisville, NC (US); Tammy Whitney, Scottsdale, AZ (US); Jeffrey D. Gengler, McKinney, TX (US)

(21) Appl. No.: 19/133,072

(22) PCT Filed: Dec. 20, 2023
(86) PCT No.: PCT/US2023/085057

§ 371 Date: May 27, 2025

Related U.S. Application Data
(60) Provisional application No. 63/435,544, filed on Dec. 27, 2022.

(51) Int. Cl. H03F 1/02; H03F 1/56; H03F 3/24

(52) U.S. Cl. CPC H03F 1/0288; H03F 1/56; H03F 3/24; H03F 2200/198

(57) ABSTRACT

Embodiments of an amplifier circuit are disclosed. In some embodiments, the amplifier circuit includes a first driver circuit and a second driver circuit. The first driver circuit connected between an input splitter circuit and a power distributor circuit, the first driver circuit having a first bias point. The second driver circuit connected between the input splitter circuit and the power distributor circuit. The second driver circuit has a second bias point that differs from the first bias point. Furthermore, a carrier amplifier circuit and a peaking amplifier circuit connected to the power distributor circuit.

### RELATED APPLICATIONS

This application claims the benefit of provisional patent application Ser. No. 63/435,544, filed Dec. 27, 2022, the disclosure of which is hereby incorporated herein by reference in its entirety.

### FIELD OF THE DISCLOSURE

The present disclosure relates generally to amplifiers, and more particularly to power distributor circuits for load modulated amplifiers.

### BACKGROUND

Doherty amplifiers are popular for having high efficiency at average output power as well as maximum output power. A Doherty amplifier generally includes a main amplifier (also known as a carrier amplifier) and an auxiliary amplifier (also known as a peaking amplifier). The main and auxiliary amplifiers are biased differently, such that the main amplifier is always providing amplification to a radio frequency (RF) signal while the auxiliary amplifier only provides amplification once the RF signal reaches a particular power level.

However, Doherty amplifier can suffer from several problems. One of those problems is that the main and the auxiliary amplifier have a gain imbalance as the Doherty amplifier is driven into compression. This imbalance causes the main amplifier to be overdriven at peak power compared to the auxiliary amplifier. Overcompressing the main amplifier generates more harmonic content leading to greater intermodulation distortion and poor linearity.

### SUMMARY

Embodiments described herein provide amplifier circuits that are operable to distributed power to a carrier amplifier circuit and to a peaking amplifier circuit as a function of input power in a Doherty amplifier. Although the embodiments are described in conjunction with Doherty amplifiers, other embodiments are not limited to this implementation. The disclosure may be applied in other amplifiers, such as load modulated balanced amplifiers. In some instances, the power distributed to the carrier amplifier circuit is limited at higher power levels going into three (3) decibels (dB) compression, and the power distributed to the peaking amplifier circuit increases at the higher power levels. In a non-limiting nonexclusive example, the power distributed to the carrier amplifier circuit is limited at higher power levels going into three (3) decibels (dB) compression, while the power distributed to the peaking amplifier circuit increases at the higher power levels as it reaches saturation.

In some embodiments an amplifier circuit, includes: a first driver circuit connected between an input splitter circuit and a power distributor circuit, the first driver circuit having a first bias point; a second driver circuit connected between the input splitter circuit and the power distributor circuit, the second driver circuit having a second bias point that differs from the first bias point; and a carrier amplifier circuit and a peaking amplifier circuit connected to the power distributor circuit. In some embodiments, the first driver circuit is a class AB amplifier circuit; and the second driver circuit is a class C amplifier circuit. In some embodiments, the amplifier circuit is a Doherty amplifier circuit. In some embodiments, the amplifier circuit further includes the input splitter; and the power distributor circuit. In some embodiments, the amplifier circuit further includes an amplifier connected to a first input terminal of the input splitter. In some embodiments, the amplifier circuit further includes a terminal impedance connected to a second input terminal of the input splitter. In some embodiments, the first driver circuit is connected to a first output terminal of the input splitter; the second driver circuit is connected to a second output terminal of the input splitter. In some embodiments, the peaking amplifier circuit contributes power and changes a load state such that the peaking carrier amplifier circuit is load modulated from an efficient match to a power match. In some embodiments, the amplifier circuit further includes a first phase shifter connected between the input splitter and the first driver circuit; a second phase shifter connected between the input splitter and the second driver circuit. In some embodiments, the amplifier circuit further includes a first balanced power amplifier (BPA) circuit connected to the power distributor circuit. In some embodiments, the amplifier circuit further includes a second BPA circuit connected to the power distributor circuit. In some embodiments, the amplifier circuit further includes a coupler circuit connected to the first BPA circuit and the second BPA circuit.

In some embodiments an amplifier circuit, includes: an input splitter circuit connected to a first phase shifter circuit and a second phase shifter circuit; a first driver circuit connected between the first phase shifter circuit and a power distributor circuit, the first driver circuit having a first bias point; a second driver circuit connected between the second phase shifter circuit and the power distributor circuit, the second driver circuit having a second bias point that differs from the first bias point; and a carrier amplifier circuit and a peaking amplifier circuit connected to the power distributor circuit. In some embodiments, the first driver circuit is a class AB amplifier circuit; and the second driver circuit is a class C amplifier circuit. In some embodiments, the amplifier circuit is a Doherty amplifier circuit. In some embodiments, the amplifier circuit further includes the power distributor circuit. In some embodiments, the amplifier circuit further includes an amplifier connected to a first input terminal of the input splitter. In some embodiments, the amplifier circuit further includes a terminal impedance connected to a second input terminal of the input splitter.

In some embodiments, an amplifier circuit, includes: an input splitter circuit connected to a first driver circuit and a second driver circuit, the first driver circuit having a first bias point and the second driver circuit having a second bias point that differs from the first bias point; a power distributor circuit connected to the first driver circuit and the second driver circuit; a first balanced power amplifier (BPA) circuit connected to the power distributor circuit; a second BPA circuit connected to the power distributor circuit; and a coupler circuit connected to the first BPA circuit and the second BPA circuit. In some embodiments, the first driver circuit is a class AB amplifier circuit; and the second driver circuit is a class C amplifier circuit.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates a block diagram of a first amplifier circuit according to embodiments of the disclosure;

FIGS. 2A-2C illustrate example input signals and output signals for the power distributor circuit shown in FIG. 1 according to embodiments of the disclosure;

FIG. 3 illustrates an example graph of signals received at the carrier amplifier and the peaking amplifier shown in FIG. 1 according to embodiments of the disclosure;

FIG. 4 illustrates a block diagram of a second amplifier circuit according to embodiments of the disclosure;

FIG. 5 illustrates an example first graph of a plot of the power in the signal output from the first driver circuit and a plot of the power in the signal output from the second driver circuit shown in FIG. 4 at a phase difference of ten (10) degrees according to embodiments of the disclosure;

FIG. 6 illustrates an example second graph of a plot of the power in the signal output from the first driver circuit and a plot of the power in the signal output from the second driver circuit shown in FIG. 4 at a phase difference of twenty (20) degrees according to embodiments of the disclosure;

FIG. 7 illustrates an example third graph of a plot of the power in the signal output from the first driver circuit and a plot of the power in the signal output from the second driver circuit shown in FIG. 4 at a phase difference of thirty (30) degrees according to embodiments of the disclosure;

FIG. 8 illustrates an example fourth graph of a plot of the power in the signal output from the first driver circuit and a plot of the power in the signal output from the second driver circuit shown in FIG. 4 at a phase difference of forty (40) degrees according to embodiments of the disclosure;

FIG. 9 illustrates an example fifth graph of a plot of the power in the signal output from the first driver circuit and a plot of the power in the signal output from the second driver circuit shown in FIG. 4 at a phase difference of fifty (50) degrees according to embodiments of the disclosure;

FIG. 10 illustrates an example sixth graph of a plot of the power in the signal output from the first driver circuit and a plot of the power in the signal output from the second driver circuit shown in FIG. 4 at a phase difference of sixty (60) degrees according to embodiments of the disclosure;

FIG. 11 illustrates a block diagram of a third amplifier circuit according to embodiments of the disclosure;

FIG. 12 illustrates a flowchart of a method of operating an amplifier circuit according to embodiments of the disclosure; and

FIG. 13 illustrates a block diagram of example user elements that may include one or more amplifier circuits in accordance with the embodiments.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It should be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It should also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It should be understood that, although the terms “upper,” “lower,” “bottom,” “intermediate,” “middle,” “top,” and the like may be used herein to describe various elements, these elements should not be limited by these terms. These terms are only used to distinguish one element from another. For example, a first element could be termed an “upper” element and, similarly, a second element could be termed an “upper” element depending on the relative orientations of these elements, without departing from the scope of the present disclosure.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having meanings that are consistent with their meanings in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

A power distributor circuit 114 is connected between the first driver circuit 106 and the second driver circuit 108 and a carrier amplifier circuit 116 and a peaking amplifier circuit 118. An output of the first driver circuit 106 is connected to a first input of the power distributor circuit 114, and an output of the second driver circuit 108 is connected to a second input of the power distributor circuit 114. A first output of the power distributor circuit 114 is connected to an input of the carrier amplifier circuit 116, and a second output of the power distributor circuit 114 is connected to an input of the peaking amplifier circuit 118.

An output of the carrier amplifier circuit 116 and an output of the peaking amplifier circuit 118 are connected together at node 120. An input of output circuitry 122 is connected to the node 120. Thus, the output of the carrier amplifier circuit 116 and the output of the peaking amplifier circuit 118 are connected to the input of the output circuitry 122.

In certain embodiments, the input splitter circuit 102 is implemented as a hybrid splitter circuit, and the power distributor circuit 114 as a hybrid distributor circuit. The input circuitry 104 can be, for example, a radio frequency (RF) source connected to a digital-to-analog converter (DAC) circuit, where an output of the DAC circuit is connected to the input splitter circuit 102 (or to the amplifier circuit 112 if the amplifier circuit 112 is included in the first amplifier circuit 100). The output circuitry 122 may be RF output circuitry. The RF output circuitry may include an RF system (e.g., an isolator circuit, a filter circuit, etc.) connected to an antenna.

The first driver circuit 106 and the second driver circuit 108 form a dual driver amplifier circuit 124. The first driver circuit 106 has a first biasing state and the second driver circuit 108 has a second biasing state, where the first biasing state differs from the second biasing state. In a non-limiting nonexclusive example, the first driver circuit 106 is a class AB amplifier circuit and the second driver circuit 108 is a class C amplifier circuit. The first driver circuit 106 and the second driver circuit 108 can be different types of amplifier circuits that have differing biasing states. For example, the first driver circuit 106 can be a class F amplifier circuit and the second driver circuit 108 the class C amplifier circuit. The first biasing state is referred to herein as a first biasing point and the second biasing state is referred to as a second biasing point.

The dual driver amplifier circuit 124 is operable to provide a gain and a power level for average power as well as peak power. In a non-limiting nonexclusive example, the first driver circuit 106 provides the gain and the power level for the average power while the second driver circuit 108 provides the peak power. The power distributor circuit 114 is operable to distribute the input power received from the first driver circuit 106 and the second driver circuit 108 as the input power sweeps between low power and high power. At times, the power distributor circuit 114 limits the power to the carrier amplifier circuit 116 to keep the carrier amplifier circuit 116 in a fixed compression state while providing increasing input power to the peaking amplifier circuit 118 to lead the peaking amplifier circuit 118 to the compression state. In a non-limiting nonexclusive example, the compression state is a three (3) decibel (dB) compression state. A terminal impedance 110 is connected to one of the input terminal of the input splitter 102.

For example, at an average power of the first amplifier circuit 100, the carrier amplifier circuit 116 is the only amplifier circuit turned on and operating. Thus, the input power is received at the carrier amplifier circuit 116. As the input power increases, the peaking amplifier circuit 118 turns on and the increasing levels of the input power are received at the peaking amplifier circuit 118, while the input power received at the carrier amplifier circuit 116 remains at a given level to keep the carrier amplifier circuit 116 in the compression state. T.

In some embodiments, the input splitter circuit 102 and the power distributor circuit 114 are implemented with the same components, although other embodiments are not limited to this configuration. One example of the component is a three (3) dB coupler circuit.

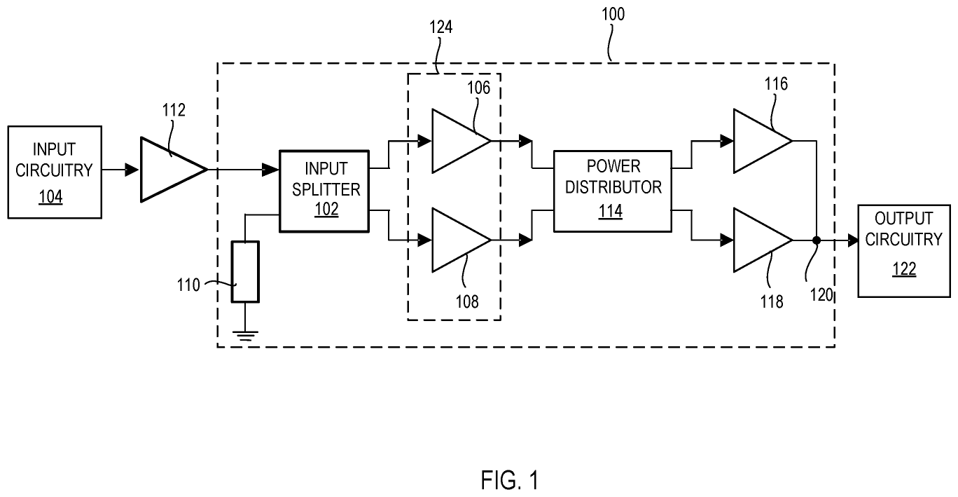

In other embodiments, the power distributor circuit 114 is implemented with an input splitter circuit, a first driver circuit, a second driver circuit, and a power distributor circuit. The power distributor circuit 114 is constructed similar to the input splitter circuit 102, the first driver circuit 106, the second driver circuit 108, and the power distributor circuit 114 shown in FIG. 1. The bias of the first driver circuit 106 (e.g., a class AB amplifier) and the bias of the second driver circuit 108 (e.g., a class C amplifier) are selected and/or adjusted to set the distribution function of the power distributor circuit 114 to a particular distribution between the carrier amplifier circuit 116 and the peaking amplifier circuit 118.

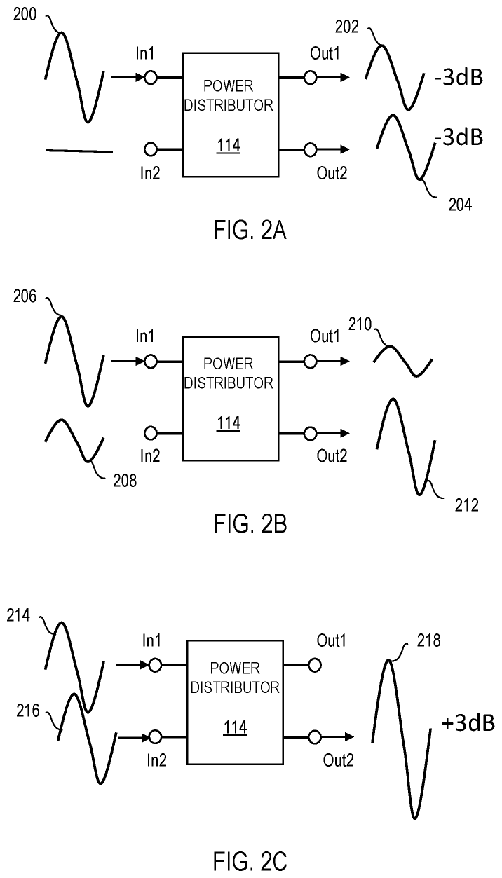

FIGS. 2A-2C illustrate example input signals and output signals for the power distributor circuit 114 shown in FIG. 1 according to embodiments of the disclosure. In FIGS. 2A-2C, a first input signal is received from the first driver circuit 106 (e.g., the class AB amplifier), a second input signal is received from the second driver circuit 108 (e.g., the class C amplifier), a first output signal is received by the carrier amplifier circuit 116, and a second output signal is received by the peaking amplifier circuit 118.

In FIG. 2A, the first input signal 200 and the second input signal are unequal in that there is only the first input signal 200. The first input signal 200 is received at a first input (IN1) port of the power distributor circuit 114 while there is no input signal at a second input (In2) port. The power distributor circuit 114 splits the first input signal 200 equally into a first output signal 202 at a first output (Out1) port and a second output signal 204 at a second output (Out2) port. The first output signal 202 and the second output signal 204 have the same amplitude but are phase shifted by ninety (90) degrees. The first output signal 202 is provided to the carrier amplifier circuit 116 and the second output signal 204 is provided to the peaking amplifier circuit 118. In the illustrated embodiment, the first output signal 202 and the second output signal 204 are each negative three (−3) dB signals.

In FIG. 2A, the first input signal 200 and the second input signal are unequal in that there is only the first input signal 200. The first input signal 200 is received at a first input (IN1) port of the power distributor circuit 114 while there is no input signal at a second input (In2) port. The power distributor circuit 114 splits the first input signal 200 equally into a first output signal 202 at a first output (Out1) port and a second output signal 204 at a second output (Out2) port. The first output signal 202 and the second output signal 204 have the same amplitude but are phase shifted by ninety (90) degrees. The first output signal 202 is provided to the carrier amplifier circuit 116 and the second output signal 204 is provided to the peaking amplifier circuit 118. In the illustrated embodiment, the first output signal 202 and the second output signal 204 are each negative three (−3) dB signals.

FIG. 2C illustrates example input signals and output signals where the first input signal 214 at the first input (In1) port has the same amplitude as the second input signal 216 at the second input (In2) port. In such embodiments, the there is no first output signal at the first output (Out1) port and the second output (Out2) port outputs a second output signal 218. Thus, all power is provided to the peaking amplifier circuit 118. In the illustrated embodiment, the second output signal 218 is a positive three (+3) dB signal.

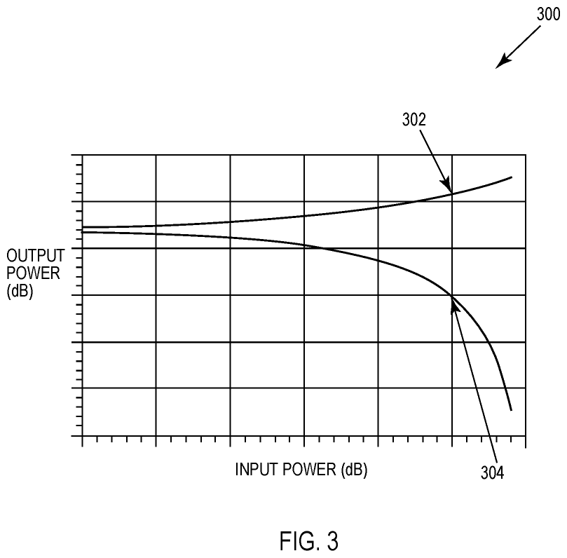

FIG. 3 illustrates an example graph 300 of a plot 302 of a signal received at the peaking amplifier circuit 118 and a plot 304 of a signal received at the carrier amplifier circuit 116 shown in FIG. 1 according to embodiments of the disclosure. As shown in FIG. 1, the signals are received from the power distributor circuit 114. The vertical axis represents output power (in dB), and the horizontal axis represents input power (in dB).

FIG. 3 illustrates an example graph 300 of a plot 302 of a signal received at the peaking amplifier circuit 118 and a plot 304 of a signal received at the carrier amplifier circuit 116 shown in FIG. 1 according to embodiments of the disclosure. As shown in FIG. 1, the signals are received from the power distributor circuit 114. The vertical axis represents output power (in dB), and the horizontal axis represents input power (in dB).

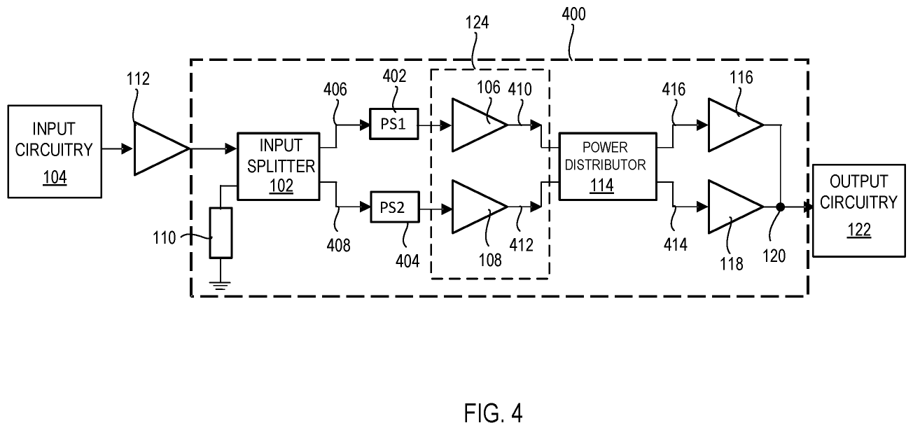

FIG. 4 illustrates a block diagram of a second amplifier circuit 400 according to embodiments of the disclosure. The second amplifier circuit 400 is similar to the first amplifier circuit 100 shown in FIG. 1 with the exception of the first phase shifter (PS1) circuit 402 and the second phase shifter (PS2) circuit 404. The PS1 circuit 402 is operable to shift a phase of the input signal on signal line 406. The PS2 circuit 404 is operable to shift a phase of the input signal on signal line 408. The PS1 circuit 402 and the PS2 circuit 404 are used to control and adjust a phase difference between the signal on signal line 410 and the signal on signal line 412, respectively. A phase difference between the signal on signal line 410 and the input signal on signal line 412 can be used to control and adjust the distribution of the power by the power distributor circuit 114.

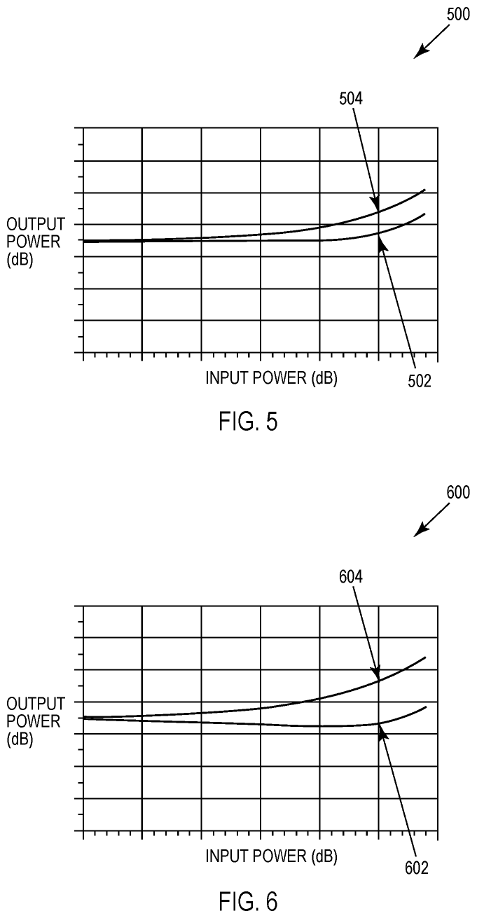

FIGS. 5-10 depict the signals input into the power distributor circuit 114 at different phase differences between the signal on signal line 410 and the signal on signal line 412. The signal on signal line 410 is received by the carrier amplifier circuit 116 and the signal on signal line 412 is received by the peaking amplifier circuit 118. In FIGS. 5-10, the horizontal axis represents power input into the first driver circuit 106 and input into the second driver circuit 108. The vertical axis represents power output from the first driver circuit 106 onto the signal line 410 and power output from the second driver circuit 108 onto the signal line 412.

FIG. 5 illustrates an example first graph 500 of a plot 502 of the power in the signal output from the first driver circuit 106 and a plot 504 of the power in the signal output from the second driver circuit 108 shown in FIG. 4 at a phase difference of ten (10) degrees according to embodiments of the disclosure. As the input power increases, the plot 504 corresponds to the plot 502, but the power output from the second driver circuit 108 (on the signal line 412) increases faster at the higher input power levels compared to the power output from the first driver circuit 106 (on the signal line 410).

FIG. 6 illustrates an example second graph 600 of a plot 602 of the power in the signal output from the first driver circuit 106 and a plot 604 of the power in the signal output from the second driver circuit 108 shown in FIG. 4 at a phase difference of twenty (20) degrees according to embodiments of the disclosure. As the input power increases, the plot 604 corresponds to the plot 602, but the power in plot 604 increases faster at the higher input power levels compared to the power in plot 602. The power in the plot 602 increases slower at the higher input power levels compared to the power in plot 504 (FIG. 5). Also, compared to FIG. 5, the increased phase shift of twenty (20) degrees causes the power in the plot 604 to increase faster compared to the power in the plot 504, and causes the difference between the power shown in the plot 602 and the power in the plot 604 to be greater than the difference between plot 502 and plot 504.

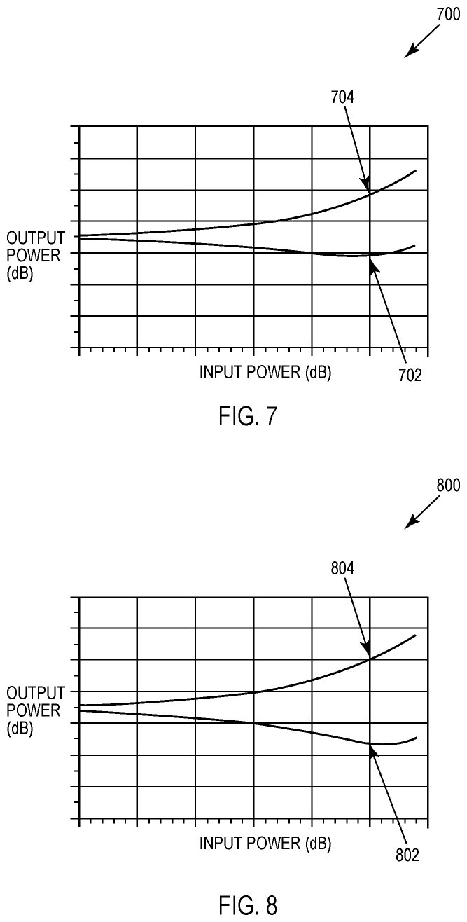

FIG. 7 illustrates an example third graph 700 of a plot 702 of the power in the signal output from the first driver circuit 106 and a plot 704 of the power in the signal output from the second driver circuit 108 shown in FIG. 4 at a phase difference of thirty (30) degrees according to embodiments of the disclosure. As the input power increases, the power in plot 704 increases faster at the higher input power levels compared to the power in plot 702, and compared to the previous plots 504 and 604. The power in plot 702 falls slightly at the higher input power levels. Also, compared to FIGS. 5 and 6, the increased phase shift of thirty (30) degrees causes the difference between the power shown in the plot 702 and the power in the plot 704 to be greater than the differences between the plot 502 and the plot 504, and between the plot 602 and the plot 604.

FIG. 8 illustrates an example fourth graph 800 of a plot 802 of the power in the signal output from the first driver circuit 106 and a plot 804 of the power in the signal output from the second driver circuit 108 shown in FIG. 4 at a phase difference of forty (40) degrees according to embodiments of the disclosure. As the input power increases, the power in the plot 804 increases faster at the higher input power levels compared to the power in the plot 802, and compared to the previous plots 504, 604, and 704. The power in the plot 802 is less at the higher input power levels than at the lower input power levels. Also, compared to FIGS. 5-7, the increased phase shift of forty (40) degrees causes the difference between the power shown in the plot 802 and the power in the plot 804 to be greater than the differences between the corresponding plots in FIGS. 5-7.

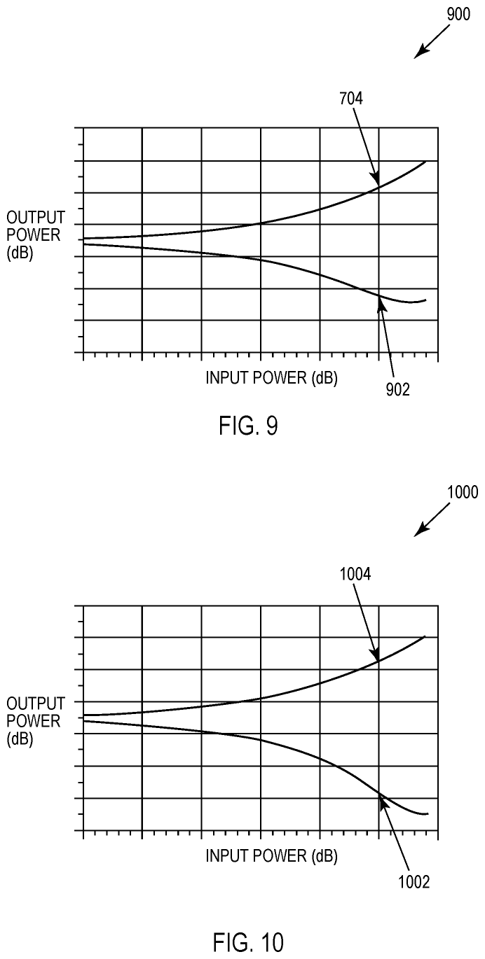

FIG. 9 illustrates an example fifth graph 900 of a plot 902 of the power in the signal output from the first driver circuit 106 and a plot 904 of the power in the signal output from the second driver circuit 108 shown in FIG. 4 at a phase difference of fifty (50) degrees according to embodiments of the disclosure. As the input power increases, the power in the plot 904 increases faster at the higher input power levels compared to the power in the plot 902, and compared to the previous plots 504, 604, 704, and 804. The power in the plot 902 is less at the higher input power levels than at the lower input power levels. Also, compared to FIGS. 5-8, the increased phase shift of fifty (50) degrees causes the difference between the power shown in the plot 902 and the power in the plot 904 to be greater than the differences between the corresponding plots in FIGS. 5-8.

FIG. 10 illustrates an example sixth graph 1000 of a plot 1002 of the power in the signal output from the first driver circuit 106 and a plot 1004 of the power in the signal output from the second driver circuit 108 shown in FIG. 4 at a phase difference of sixty (60) degrees according to embodiments of the disclosure. As the input power increases, the power in the plot 1004 increases faster at the higher input power levels compared to the power in the plot 1002, and compared to the previous plots 504, 604, 704, 804, and 904. The power in the plot 1002 is less at the higher input power levels than at the lower input power levels. Also, compared to FIGS. 5-9, the increased phase shift of sixty (60) degrees causes the difference between the power shown in the plot 1002 and the power in the plot 1004 to be greater than the differences between the corresponding plots in FIGS. 5-9.

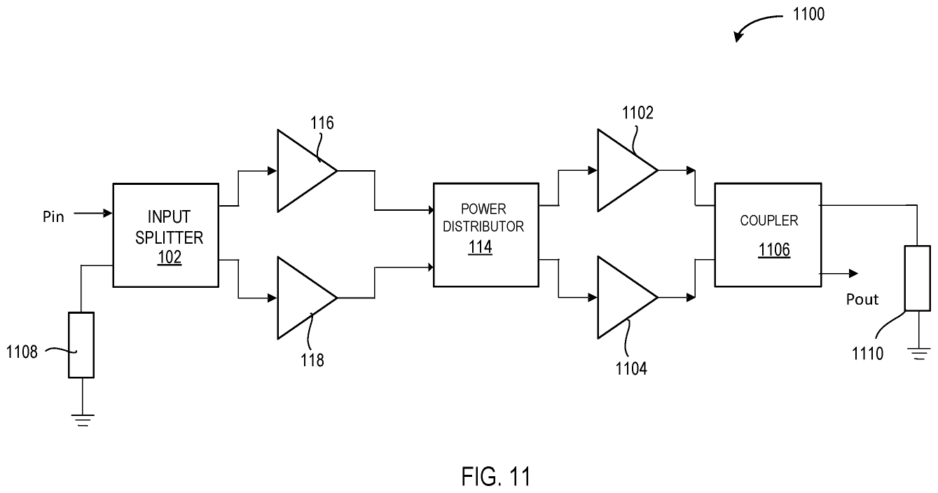

FIG. 11 illustrates a block diagram of a third amplifier circuit 1100 according to embodiments of the disclosure. The example third amplifier circuit 1100 is an orthogonal load modulated balanced amplifier circuit. The carrier amplifier circuit 116 and the peaking amplifier circuit 118 are connected between the input splitter circuit 102 and the power distributor circuit 114. A first balanced power amplifier (BPA) circuit 1102 and a second BPA circuit 1104 are connected between the power distributor circuit 114 and a coupler circuit 1106.

In particular, a first output of the input splitter circuit 102 is connected to an input of the carrier amplifier circuit 116, and a second output of the input splitter circuit 102 is connected to an input of the peaking amplifier circuit 118. An output of the carrier amplifier circuit 116 is connected to a first input of the power distributor circuit 114. An output of the peaking amplifier circuit 118 is connected to a second input of the power distributor circuit 114. A first output of the power distributor circuit 114 is connected to an input of the first BPA circuit 1102, and a second output of the power distributor circuit 114 is connected to an input of the second BPA circuit 1104. An output of the first BPA circuit 1102 is connected to a first input of the coupler circuit 1106. An output of the second BPA circuit 1104 is connected to a second input of the coupler circuit 1106.

A first load 1108 can be connected to a first input of the input splitter circuit 102. An input pin (Pin) is connected to a second input of the input splitter circuit 102. A second load 1110 may be connected to a first output of the coupler circuit 1106. An output pin (Pout) is connected to a second output of the coupler circuit 1106. The power distributor circuit 114 operates in a similar manner as the power distributor circuit 114 in FIGS. 2A-2C and FIG. 4. The power distributor circuit 114 distributes power to the first BPA circuit 1102 and the second BPA circuit 1104 as a function of the input power.

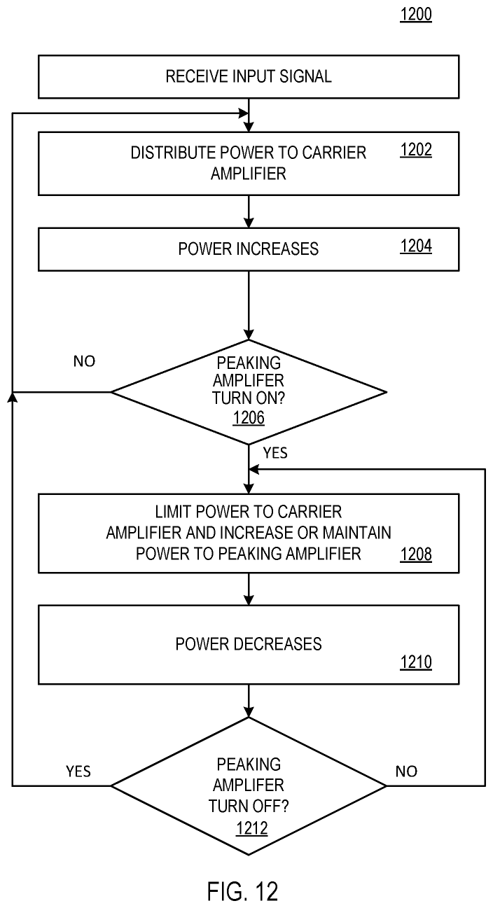

FIG. 12 illustrates a flowchart of a method of operating an amplifier circuit according to embodiments of the disclosure. Initially, as shown in block 1200, an input signal is received at the amplifier circuit. While the input signal is at a lower power level, the power is distributed to the carrier amplifier circuit (block 1202). The power level in the input signal increases at block 1204, and a determination is made at block 1206 as to whether the peaking amplifier circuit has turned on based on the current power level of the input signal. If a determination is made that the peaking amplifier circuit has not turned, on, the method returns to block 1202.

When a determination is made at block 1206 that the peaking amplifier circuit has turned on, the method continues at block 1208 where the power that is distributed to the carrier amplifier circuit is limited and the increased power is distributed to the peaking amplifier circuit. The power level decreases at block 1210, and a determination is made at block 1212 as to whether the peaking amplifier circuit has turned off based on the current power level. If a determination is made that the peaking amplifier circuit has not turned off (e.g., is still turned on), the method returns to block 1208. When a determination is made at block 1212 that the peaking amplifier circuit has turned off, the method continues at block 1202.

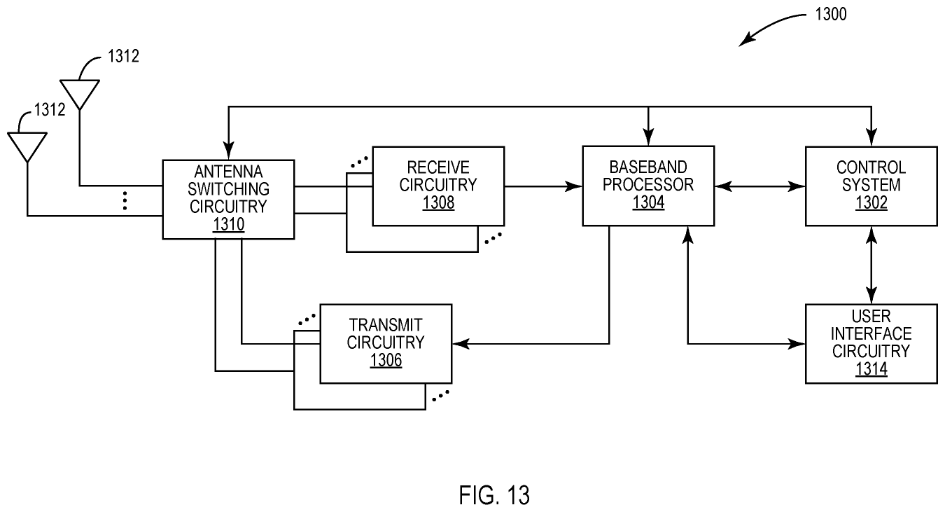

FIG. 13 illustrates a block diagram of example user elements that may include one or more amplifier circuits in accordance with the embodiments. The concepts described above may be implemented in various types of user elements 1300, such as mobile terminals, smart watches, tablets, computers, navigation devices, access points, and like wireless communication devices that support wireless communications, such as cellular, wireless local area network (WLAN), BLUETOOTH, and near field communications. The user elements 1300 will generally include a control system 1302, a baseband processor 1304, transmit circuitry 1306, receive circuitry 1308, antenna switching circuitry 1310, multiple antennas 1312, and user interface circuitry 1314. In a non-limiting example, the control system 1302 can be a field-programmable gate array (FPGA) or an application-specific integrated circuit (ASIC), as an example. In this regard, the control system 1302 can include at least a microprocessor(s), an embedded memory circuit(s), and a communication bus interface(s). The receive circuitry 1308 receives radio frequency signals via the antennas 1312 and through the antenna switching circuitry 1310 from one or more base stations. A low noise amplifier and a filter of the receive circuitry 1308 cooperate to amplify and remove broadband interference from the received signal for processing. Down conversion and digitization circuitry (not shown) will then down convert the filtered, received signal to an intermediate or baseband frequency signal, which is then digitized into one or more digital streams using analog-to-digital converter(s) (ADC).

The baseband processor 1304 processes the digitized received signal to extract the information or data bits conveyed in the received signal. This processing typically comprises demodulation, decoding, and error correction operations, as will be discussed on greater detail below. The baseband processor 1304 is generally implemented in one or more digital signal processors (DSPs) and application specific integrated circuits (ASICs).

For transmission, the baseband processor 1304 receives digitized data, which may represent voice, data, or control information, from the control system 1302, which it encodes for transmission. The encoded data is output to the transmit circuitry 1306, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal to the antennas 1312 through the antenna switching circuitry 1310 to the antennas 1312. The multiple antennas 1312 and the replicated transmit and receive circuitries 1306, 1308 may provide spatial diversity. Modulation and processing details will be understood by those skilled in the art.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. An amplifier circuit, comprising:
a first driver circuit connected between an input splitter circuit and a power distributor circuit, the first driver circuit having a first bias point;
a second driver circuit connected between the input splitter circuit and the power distributor circuit, the second driver circuit having a second bias point that differs from the first bias point; and
a carrier amplifier circuit and a peaking amplifier circuit connected to the power distributor circuit.

2. The amplifier circuit of claim 1, wherein:
the first driver circuit is a class AB amplifier circuit; and
the second driver circuit is a class C amplifier circuit.

3. The amplifier circuit of claim 1, wherein the amplifier circuit is a Doherty amplifier circuit.

4. The amplifier circuit of claim 1, further comprising:
the input splitter; and
the power distributor circuit.

5. The amplifier circuit of claim 1, further comprising:
an amplifier connected to a first input terminal of the input splitter.

6. The amplifier circuit of claim 5, further comprising:
a terminal impedance connected to a second input terminal of the input splitter.

7. The amplifier circuit of claim 6, wherein:
the first driver circuit is connected to a first output terminal of the input splitter;
the second driver circuit is connected to a second output terminal of the input splitter.

8. The amplifier circuit of claim 1, wherein the peaking amplifier circuit contributes power and changes a load state such that the peaking carrier amplifier circuit is load modulated from an efficient match to a power match.

9. The amplifier circuit of claim 1, further comprising:
a first phase shifter connected between the input splitter and the first driver circuit;
a second phase shifter connected between the input splitter and the second driver circuit.

10. The amplifier circuit of claim 1, further comprising:
a first balanced power amplifier (BPA) circuit connected to the power distributor circuit.

11. The amplifier circuit of claim 10, further comprising:
a second BPA circuit connected to the power distributor circuit.

12. The amplifier circuit of claim 11, further comprising:
a coupler circuit connected to the first BPA circuit and the second BPA circuit.

13. An amplifier circuit, comprising:
an input splitter circuit connected to a first phase shifter circuit and a second phase shifter circuit;
a first driver circuit connected between the first phase shifter circuit and a power distributor circuit, the first driver circuit having a first bias point;
a second driver circuit connected between the second phase shifter circuit and the power distributor circuit, the second driver circuit having a second bias point that differs from the first bias point; and
a carrier amplifier circuit and a peaking amplifier circuit connected to the power distributor circuit.

14. The amplifier circuit of claim 13, wherein:
the first driver circuit is a class AB amplifier circuit; and
the second driver circuit is a class C amplifier circuit.

15. The amplifier circuit of claim 13, wherein the amplifier circuit is a Doherty amplifier circuit.

16. The amplifier circuit of claim 13, further comprising the power distributor circuit.

17. The amplifier circuit of claim 13, further comprising:
an amplifier connected to a first input terminal of the input splitter.

18. The amplifier circuit of claim 17, further comprising:
a terminal impedance connected to a second input terminal of the input splitter.

19. An amplifier circuit, comprising:
an input splitter circuit connected to a first driver circuit and a second driver circuit, the first driver circuit having a first bias point and the second driver circuit having a second bias point that differs from the first bias point;
a power distributor circuit connected to the first driver circuit and the second driver circuit;
a first balanced power amplifier (BPA) circuit connected to the power distributor circuit;
a second BPA circuit connected to the power distributor circuit; and
a coupler circuit connected to the first BPA circuit and the second BPA circuit.

20. The amplifier circuit of claim 19, wherein:
the first driver circuit is a class AB amplifier circuit; and
the second driver circuit is a class C amplifier circuit.
